(19) United States
(12) Patent Application Publication
(10) Pub. No.: US 2025/0357119 A1
(43) Pub. Date: Nov. 20, 2025

(54) Semiconductor stitching structure and manufacturing method thereof

(71) Applicant: UNITED MICROELECTRONICS CORP., Hsin-Chu City (TW)

(72) Inventors: Yi-Chang Huang, Tainan City (TW); Mei-Shiuan Wu, Tainan City (TW); Ming-Che Tsai, Tainan City (TW); Chih-Chiang Wu, Tainan City (TW); Cheng-Tzung Tsai, Taipei City (TW); Hon-Chun Wang, Taichung City (TW); Wan-Chun Liao, Hsinchu County (TW)

(73) Assignee: UNITED MICROELECTRONICS CORP., Hsin-Chu City (TW)

(21) Appl. No.: 18/744,715

(22) Filed: Jun. 17, 2024

(30) Foreign Application Priority Data
May 20, 2024 (TW) 113118617

(51) Int. Cl. H01L 21/033; H01L 21/027; H01L 21/68; H01L 23/544

(52) U.S. Cl. CPC H01L 21/0337; H01L 23/544; H01L 2223/54426

(57) ABSTRACT

The invention provides a semiconductor stitching structure, which comprises a substrate, a first mask pattern is defined on the substrate, the first mask pattern comprises a first component layout region and a first stitching region, and a second mask pattern is defined on the substrate, the second mask pattern comprises a second component layout region and a second stitching region, and an overlapping stitching region, wherein the overlapping stitching region is the overlapping part of the first stitching region of the first mask pattern and the second stitching region of the second mask pattern, and a plurality of bridging wires located on the substrate in the overlapping stitching region, and a plurality of alignment marks located in the first component layout region on the substrate.

### BACKGROUND OF THE INVENTION

### 1. Field of the Invention

The present invention relates to the field of semiconductor processes, and more particularly to a semiconductor stitching structure with a reduced stitching area, which has the advantage of enlarging the effective component layout area.

### 2. Description of the Prior Art

With advancements in semiconductor manufacturing processes, the size of components that can be accommodated within a unit area of a semiconductor device is decreasing, and component density is increasing. At the same time, the size of the die is also gradually increasing to accommodate more components. However, while increasing the die area, if the die area exceeds the limit value of the mask pattern in the exposure step, patterns cannot be formed outside the exposure range, thus limiting the formation of components and hindering the development of large die technology.

Referring to current process technologies, the maximum exposure area of an exposure machine in a single exposure is called a shot. With current technologies, the shot area is about 26 mm×33 mm. However, when the area of the pattern to be formed exceeds the aforementioned shot area, the required pattern cannot be formed in a single exposure. Therefore, to form the required pattern, multiple masks and multiple exposure processes are needed to form patterns in different areas separately, and then these patterns are stitched together to form a larger pattern that meets the needs of larger area dies.

### SUMMARY OF THE INVENTION

The invention provides a semiconductor stitching structure, which comprises a substrate; a first mask pattern is defined on the substrate; the first mask pattern comprises a first component layout region and a first stitching region; a second mask pattern is defined on the substrate; the second mask pattern comprises a second component layout region and a second stitching region, and an overlapping stitching region, wherein the overlapping stitching region is the overlapping part of the first stitching region of the first mask pattern and the second stitching region of the second mask pattern; and

The invention also provides a method for manufacturing a semiconductor stitching structure, which comprises providing a substrate, Providing a first mask pattern and a second mask pattern, forming the first mask pattern on a substrate, wherein the first mask pattern comprises a first component layout region, a first stitching region and a plurality of first alignment marks, and forming the second mask pattern on the substrate, wherein the second mask pattern comprises a second component layout region, a second stitching region and a plurality of second alignment marks, and the overlapping part of the first stitching region and the second stitching region is defined as an overlapping stitching region.

The invention is characterized by providing a semiconductor stitching structure and a manufacturing method thereof. The semiconductor stitching structure is formed on a substrate or a material layer by a first photomask and a second photomask through respective exposure processes. It is worth noting that since the first alignment mark on the first photomask is set in the first component layout region, the area of the first stitching region of the first photomask can be minimized. For example, the width of the second stitching region on the second photomask is about 200 microns, but the width of the first stitching region of the first photomask only needs to be 0.2 microns. In addition, the invention can also be applied to stitching patterns of more different masks. By using the structure and method provided by the invention, when two mask patterns are adjacent to each other and stitched, the stitching region of one mask can be reduced to almost negligible, so compared with the traditional technology, the area of the stitching region can be reduced by about half, thereby improving the space of the component layout region on the mask and improving the component density. The invention is suitable for manufacturing large-area chips, such as display chips, or applied to fields such as VR (virtual reality) and AR (augmented reality).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a schematic top view of a first mask pattern and a second mask pattern according to a first embodiment of the present invention.

FIG. 2 is a schematic top view showing the overlapping of a first mask pattern and a second mask pattern after being formed on a substrate according to the first embodiment of the present invention.

FIG. 3 is a schematic top view of a first mask pattern and a second mask pattern according to a second embodiment of the present invention.

FIG. 4 is a schematic top view showing the overlapping of a first mask pattern and a second mask pattern after being formed on a substrate according to a second embodiment of the present invention.

FIG. 5 is a schematic top view of a first mask pattern, a second mask pattern, a third mask pattern and a fourth mask pattern according to a third embodiment of the present invention.

FIG. 6 is a schematic top view of a first mask pattern, a second mask pattern, a third mask pattern and a fourth mask pattern according to a third embodiment of the present invention after being formed on a substrate.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

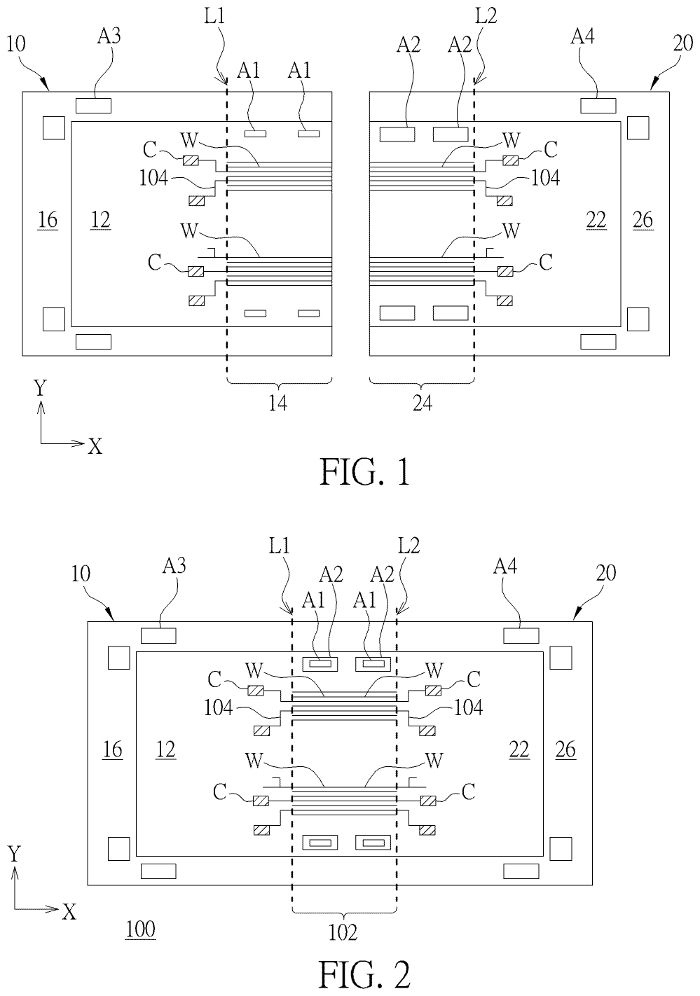

Please refer to FIG. 1 and FIG. 2. FIG. 1 shows a schematic diagram of a first mask pattern and a second mask pattern according to a first embodiment of the present invention. FIG. 2 is a schematic top view showing the overlapping of a first photomask and a second photomask after being formed on a substrate according to the first embodiment of the present invention. As shown in FIG. 1, first, a first mask pattern 10 and a second mask pattern 20 are provided, wherein the first mask pattern 10 and the second mask pattern 20 are patterns on a first photomask (not shown) and a second photomask (not shown) respectively. The first mask pattern 10 includes a first component layout region 12, a first stitching region 14 and a first peripheral region 16, and the second mask pattern 20 includes a second component layout region 22, a second stitching region 24 and a second peripheral region 26. Among them, the first component layout region 12 and the second component layout region 22 are the main regions for the subsequent formation of various electronic components C. The electronic components C include, for example, transistors, capacitors, resistors, inductors, wires, and various electronic components composed of the above electronic units, such as switches, diodes, power amplifiers, etc., all of which may be located in the first component layout region 12 and the second component layout region 22. The first peripheral region 16 is arranged at the periphery of the first component layout region 12 and the second peripheral region 26 is arranged at the periphery of the second component layout region 22. The purpose of setting the first peripheral region 16 and the second peripheral region 26 is to keep a certain space between the first component layout region 12 and the second component layout region 22 and the edges of the photomask, so as to prevent the components from being damaged if they are arranged too close to the boundary.

The first mask pattern 10 includes a first stitching region 14, and the second mask pattern 20 includes a second stitching region 24, wherein the first stitching region 14 is arranged along one side of the first mask pattern 10 (for example, the right side of the first mask pattern 10 in FIG. 1), and the second stitching region 24 is also arranged along one side of the second mask pattern 20 (for example, the left side of the second mask pattern 20 in FIG. 1). The first stitching region 14 also contains a plurality of first alignment marks A1 and bridging wires W, and the second stitching region 24 contains a plurality of second alignment marks A2 and bridging wires W. The boundary between the first stitching region 14 and the first component layout region 12 is defined as L1, while the boundary between the second stitching region 24 and the second component layout region 22 is defined as L2.

The purpose of setting the first stitching region 14 and the second stitching region 24 is that the first stitching region 14 and the second stitching region 24 will overlap when the patterns of the two photomasks (i.e., the first mask pattern 10 and the second mask pattern 20) are stitched. At this time, each first alignment mark A1 will overlap and align with each second alignment mark A2, which will be described in detail in the following paragraphs.

In addition, the first peripheral region 16 may also contain a third alignment mark A3, and the second peripheral region 26 may contain a fourth alignment mark A4. The third alignment mark A3 and the fourth alignment mark A4 are used to align the patterns of the current layer (that is, the patterns of the first mask pattern 10 and the second mask pattern 20 described here) with the patterns of the upper layer or the lower layer. However, in some embodiments, it is also possible to omit forming the third alignment mark A3 and the fourth alignment mark A4.

As shown in FIG. 1, the range of the first stitching region 14 includes a part of the first component layout region 12 and a part of the first peripheral region 16, but other components except the bridging wire W and the first alignment mark A1 are not included in the range of the first stitching region 14, that is to say, the above-mentioned electronic components C such as transistors, capacitors, resistors and inductors do not exist in the first stitching region 14. Similarly, the range of the second stitching region 24 includes a part of the second component layout region 22 and a part of the second peripheral region 26, but within the range of the second stitching region 24, other components except the bridging wire W and the second alignment mark A2 are not included, that is to say, the above-mentioned electronic components C such as transistors, capacitors, resistors and inductors do not exist in the first stitching region 24. It is worth noting that the bridging wires W located in the first stitching region 14 and the second stitching region 24 have similar functions as the wires 104 located in the first component layout region 12 and the second component layout region 22, and are also used to electrically connect the components to each other. However, the size or line width of the bridging wires W located in the first stitching region 14 and the second stitching region 24 are usually larger than that of the conductive wires 104 located in the first component layout region 12 and the second component layout region 22, because two exposure and development steps will be carried out in the stitching region. In order to avoid that the bridging wire W located in the stitching region is too thin and broken, so that the components on both sides cannot be connected, the line width of the bridging wires W are usually designed to be larger than that of the conductive wires 104. In addition, the bridging wires W in the first stitching region 14 are connected to the electronic components C in the first component layout region 12 through wires 104, and similarly, the bridging wires W in the second stitching region 24 are connected to the electronic components C in the second component layout region 22 through wires 104.

FIG. 2 is a schematic top view showing the overlapping of a first photomask and a second photomask after being formed on a substrate according to the first embodiment of the present invention. As shown in FIG. 2, the stitching step is carried out, and the first mask and the second mask are respectively exposed to form the patterns of the first mask pattern 10 and the second mask pattern 20 on a substrate 100. The sequence of exposure steps here can be as follows: first, an exposure step is performed to form a first mask pattern 10 on a first mask (not shown) on a substrate 100, and then another exposure step is performed to form a second mask pattern 20 on a second mask (not shown) on the substrate 100, wherein the first stitching region 14 of the first mask pattern 10 will be in contact with the second mask pattern 20. Alternatively, the second mask pattern 20 can be formed on the substrate 100 before the first mask pattern 10 is formed on the substrate 100, which is also within the scope of the present invention. In addition, the substrate 100 described here may include a silicon wafer substrate or a material layer in a semiconductor stacked structure, and the present invention is not limited to this, and the above variations and combinations are within the scope of the present invention.

Please continue to refer to FIG. 2. After the patterns of the first mask pattern 10 and the second mask pattern 20 are overlapped on the substrate 100, the first alignment mark A1 in the first stitching region 14 will overlap with the second alignment mark A2 in the second stitching region 24. When designing and making the pattern of the photomask, when the first alignment mark A1 and the second alignment mark A2 overlap, the bridging wires W in the first stitching region 14 and the bridging wires W in the second stitching region 24 can also overlap with each other, thereby connecting the electronic components C in the first component layout region 12 and the electronic components C in the second component layout region 22, that is, stitching the first mask pattern 10 and the second mask pattern 20.

In this embodiment, the first alignment mark A1 is designed as a rectangle, while the second alignment mark A2 is designed as a frame. The so-called alignment of the first alignment mark A1 and the second alignment mark A2 means that the rectangle of the first alignment mark A1 is located in the frame of the second alignment mark A2 and does not touch the edge of the frame of the second alignment mark A2. However, it can be understood that the shapes of the first alignment mark A1 and the second alignment mark A2 in this embodiment are not limited to this, and can be adjusted according to actual needs, and the present invention is not limited to this.

As shown in FIG. 1 and FIG. 2, it can be seen from the figure that the purpose of designing the first stitching region 14 and the second stitching region 24 is mainly to accommodate the first alignment mark A1 and the second alignment mark A2. In order to accommodate enough alignment marks in the stitching region (when there are more alignment marks in the stitching region and all alignment marks can be accurately overlapped, it means that the stitching step is more accurate at this time), the stitching region needs a certain space. However, in this way, the first stitching region 14 will occupy a part of the area of the first component layout region 12, and similarly, the second stitching region 24 will also occupy a part of the area of the second component layout region 22.

As shown in FIG. 2, after the first mask pattern 10 and the second mask pattern 20 are overlapped and stitched, the overlapping area between the first stitching region 14 and the second stitching region 24 is defined as the overlapping stitching region 102. It can be found that the overlapping stitching region 102 only contains the first alignment mark A1, the second alignment mark A2 and the bridging wire W, but other electronic components C cannot be arranged in the overlapping stitching region 102. Therefore, as mentioned above, the area of the first component layout region 12 and the second component layout region 22 will be reduced by the stitched semiconductor structure. Even when there are more stacked layers in the whole semiconductor structure, each stacked layer will further reduce the area of the component layout region.

In addition, in this embodiment, for the sake of simplicity, some elements in FIG. 1 and FIG. 2 are not numbered, such as some first alignment marks A1, second alignment marks A2, third alignment marks A3, fourth alignment marks A4, electronic components C, bridging wires W, etc., but these elements have the same characteristics as the adjacent similar elements, so those skilled in the art should be able to identify these elements without doubt and understand their characteristics. Similarly, the following embodiments also omit a part of the component numbers for the sake of simplicity, and will be described here first.

In the following, different embodiments of the semiconductor stitching structure and its manufacturing method of the present invention will be described, and in order to simplify the description, the following description will mainly focus on the differences of each embodiment, and will not repeat the similarities. In addition, the same elements in various embodiments of the present invention are labeled with the same reference numerals, so as to facilitate the comparison among various embodiments.

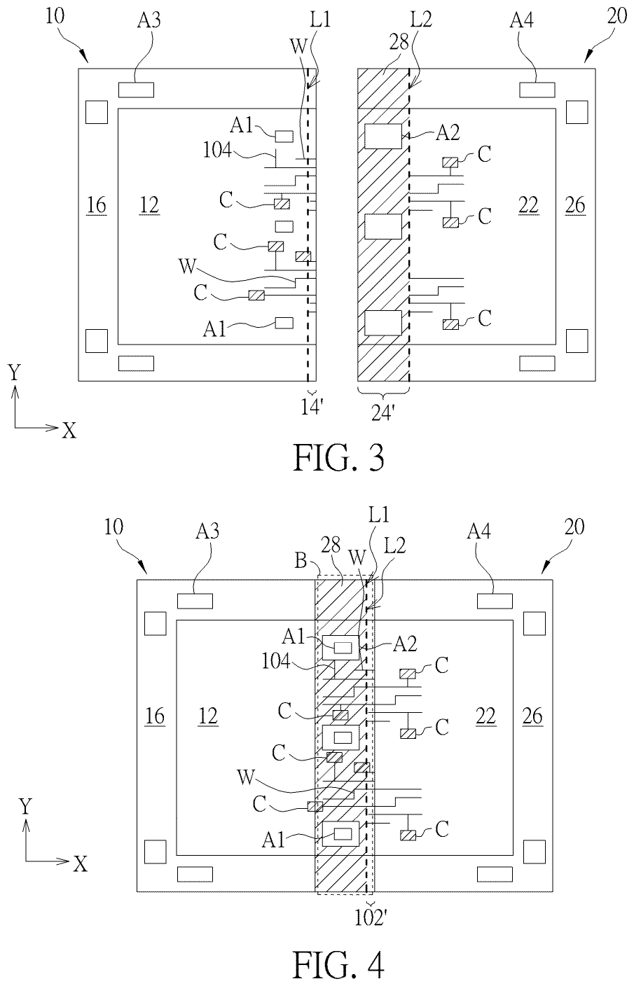

Therefore, in order to solve the problem that the number of electronic components can be reduced due to the reduction of the area of the component layout region, another embodiment of the present invention proposes an improved semiconductor stitching structure. Please refer to FIG. 3, which shows a top view of a first mask pattern and a second mask pattern according to a second embodiment of the present invention. As shown in FIG. 3, this embodiment is similar to the above-mentioned embodiment. The first mask pattern 10 includes a first component layout region 12, a first stitching region 14′ and a first peripheral region 16, and the second mask pattern 20 includes a second component layout region 22, a second stitching region 24′ and a second peripheral region 26, and may also include first alignment marks A1, second alignment marks A2, third alignment marks A3 and fourth alignment marks A4, wires 104 and bridging wires W. The elements such as the first component layout region 12, the second component layout region 22, the first peripheral region 16, the second peripheral region 26, the first alignment mark A1, the second alignment mark A2, the third alignment mark A3, the fourth alignment mark A4, the wire 104 and the bridging wire W described here are the same as those described in the first embodiment, so they are denoted by the same reference numerals. As for this embodiment, the main differences from the above-mentioned first embodiment are the area of the first stitching region 14′ and the arrangement position of the first alignment marks A1. As shown in FIG. 3, the first alignment marks A1 contained in the first mask pattern 10 in this embodiment are not located in the first stitching region 14′, but in the first component layout region 12. That is to say, the first alignment marks A1 are arranged in the same area as various electronic components C (such as transistors and wires). Since the first stitching region 14′ does not need to accommodate a plurality of first alignment marks A1, the area of the first stitching region 14′ can be greatly reduced. According to the applicant's experimental observation, the width of the first stitching region 14 in the original first embodiment (the embodiment shown in FIGS. 1-2) is about 200 microns. However, the width of the first stitching region 14′ in the second embodiment is about 0.2 micron. It is also worth noting that in order to show the position of the first stitching region 14′ in FIG. 3, the first stitching region 14′ is not presented according to the actual scale, that is to say, the actual area of the first stitching region 14′ should be much smaller than that drawn in FIG. 3. In this embodiment, only a few bridging wires W need to be left as connections in the first stitching region 14′, and the remaining first alignment marks A1 are set in the first component layout region 12 instead.

In addition, the area of the second stitching region 24′ in this embodiment is basically the same as that of the second stitching region 24 in the above-mentioned first embodiment, and it is also necessary to reserve a certain space to accommodate the second alignment mark A2. It is worth noting that the second stitching region 24′ of the second mask pattern 20 in this embodiment further includes a mask layer 28, and the material of the mask layer 28 is, for example, chromium (Cr), but not limited thereto. The mask layer 28 covers the region in the second stitching region 24′ except for the second alignment marks A2. During the stitching step, the second stitching region 24′ will overlap with a part of the first component layout region 12, especially with some electronic components C. Therefore, it is necessary to block the area except the second alignment mark A2 with the mask layer 28, so as to avoid repeated exposure of some electronic components C in the first component layout region 12 and damage those electronic components C.

FIG. 4 shows a schematic top view of a first mask pattern and a second mask pattern after being formed on a substrate according to a second embodiment of the present invention. As shown in FIG. 4, after the pattern of the first mask pattern 10 and the pattern of the second mask pattern 20 in this embodiment are overlapped on the substrate 100, the overlapping area of the first stitching region 14′ and the second stitching region 24′ is defined as an overlapping stitching region 102′. In addition, a part of the second stitching region 24′ overlaps the first component layout region 12, but the part is not the overlapping stitching region 102′ (because it does not overlap the first stitching region 14′), which is defined as the overlapping region B. The overlapping region B contains the electronic components C, the wires 104, the first alignment marks A1 and the second alignment marks A2. It can be clearly seen from FIG. 4 that since the area of the first stitching region 14′ in this embodiment is greatly reduced, the area of the overlapping stitching region 102′ is also greatly reduced. As mentioned above, the width of the first stitching region 14′ is only about 0.2 micron, so the width of the overlapping stitching region 102′ is only about 0.2 micron too. In other words, the width of the overlapping stitching region 102′ in this embodiment is only about 1/1000 compared with the width of the overlapping stitching region 102 in the embodiment shown in FIG. 2, so more area is reserved in the first component layout region 12, the area of the first component layout region 12 in this embodiment is also larger than that of the first component layout region 12 in the first embodiment, and more electronic components C can be accommodated in the first component layout region 12 of this embodiment.

It is worth noting that in the drawings of the present invention, for the sake of simplicity, the electronic components C and the wires 104 are only drawn in a part of the component layout region, but it can be understood that in some embodiments, in order to effectively utilize the area of the component layout region, the electronic components C and the wires 104 may be arranged the whole component layout region.

It is worth noting that the first stitching region 14′ in this embodiment only contains the bridging wire W and no other electronic components, and the other electronic components, such as the first alignment marks A1, are all arranged in the first component layout region 12. In order to enlarge the area of the first component layout region 12 as much as possible to accommodate more electronic components C, it is preferable to use the extra area to arrange the electronic components C. That is to say, the electronic components C will be arranged in the first component layout region 12 adjacent to the first stitching region 14′. Different from the first stitching region 14 in the first embodiment, the first stitching region 14′ and the second stitching region 24′ in this embodiment have different areas, and the first component layout region 12 adjacent to the first stitching region 14′ in this embodiment has the first alignment marks A1 and electronic components C (such as transistors) disposed therein, and these electronic components C may be arranged around the first alignment marks A1. For example, around the first alignment marks A1 in the first component layout region 12, there are wires 104 or other electronic components C. As shown in FIG. 4, in the first component layout region 12, the upper or lower (+ or − Y direction) of the first alignment mark A1 includes wires 104 for connecting the electronic components C (the wires 104 here are similar to the bridging wires W, but usually has thinner line widths) and the electronic components C (such as a transistors).

In addition, the semiconductor stitching structure of this embodiment has some features. From FIG. 4, after the first mask pattern 10 and the second mask pattern 20 are stitched, one of the features is that the first alignment marks A1 are arranged in the first component layout region 12, but not in the overlapping stitching region 102′. Furthermore, the arrangement direction of the first alignment marks A1 and the second alignment marks A2 is parallel to the direction of the dividing line L1 (that is, the Y direction in FIG. 4), so although the first alignment marks A1 and the second alignment marks A2 are arranged around some electronic components C, they will not excessively affect the arrangement of these electronic components C. In addition, the overlapping stitching region 102′ shown in FIG. 4 only contains the bridging wires W, and does not contain other electronic components C including the first alignment marks A1 or transistors. In addition, from the structure of FIG. 4, both the first alignment marks A1 and the second alignment marks A2 are located on one side of the overlapping stitching region 102′, that is to say, the first alignment marks A1 and the second alignment marks A2 are not included in the second component layout region 22.

In addition, it is worth noting that the difference between the overlapping region B and the overlapping stitching region 102′ in this embodiment is that the overlapping stitching region 102′ contains bridging wires W, so the overlapping stitching region 102′ is the main area for stitching two patterns. While the overlapping region B is an area where two patterns overlap but are not used for stitching, that is to say, the area of the overlapping region B can be regarded as the area additionally reserved in the first component layout region 12 (compared with the first embodiment). In other words, the larger the area of the overlapping region B, the more usable area the first component layout region 12 of this embodiment increases compared with the first embodiment.

Therefore, with the semiconductor stitching structure of the second embodiment of the present invention, the area of the first stitching region 14′ can be greatly reduced, and further more usable area of the first component layout region 12 can be reserved, so as to accommodate more electronic components in a limited space.

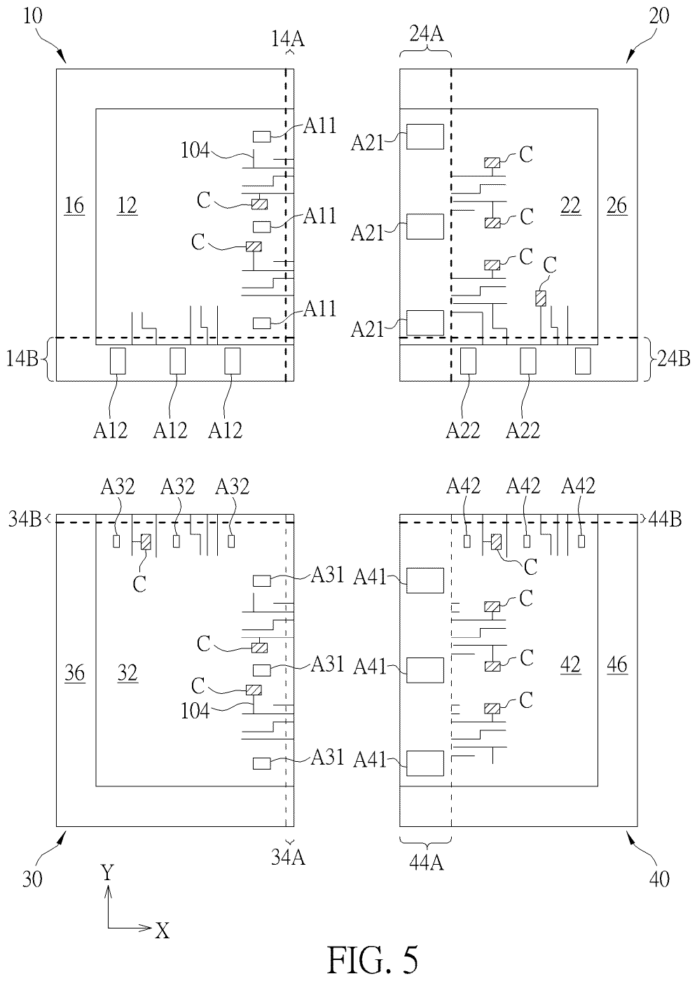

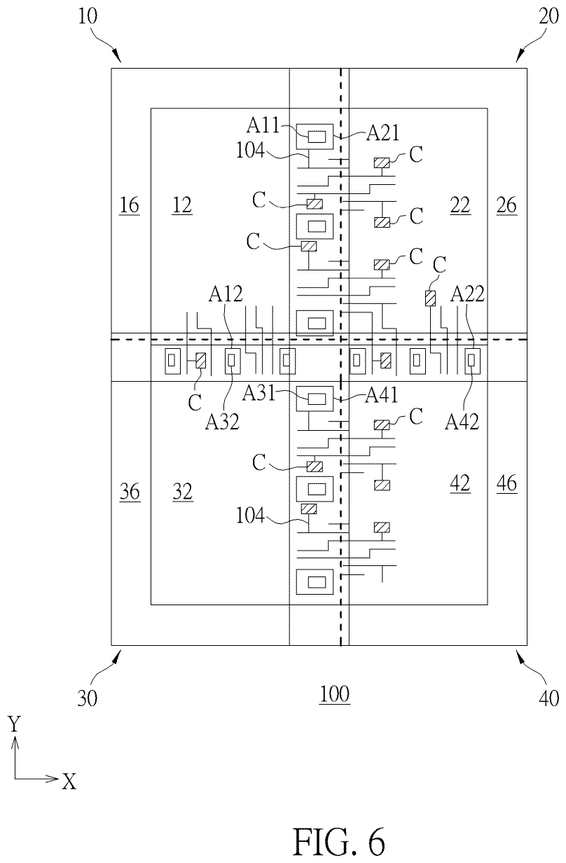

The concept of the second embodiment described above can also be applied to a semiconductor stitching structure in which a plurality of mask patterns are stitched with each other. That is to say, it can be applied to stitching more than two mask patterns. Please refer to FIG. 5 and FIG. 6. FIG. 5 shows a top view of a first mask pattern, a second mask pattern, a third mask pattern and a fourth mask pattern according to a third embodiment of the present invention, and FIG. 6 shows a top view of the first mask pattern, the second mask pattern, the third mask pattern and the fourth mask pattern after being formed on a substrate according to the third embodiment of the present invention. The concept of this embodiment is similar to the above embodiment, but this embodiment includes a first mask pattern 10, a second mask pattern 20, a third mask pattern 30 and a fourth mask pattern 40, which belong to patterns on four different photomasks respectively. It is expected that the patterns of four photomasks will be formed on the substrate 100 by respective exposure and development steps, and then the patterns will be stitched with each other. In this embodiment, the first mask pattern 10 includes a first component layout region 12, a stitching region 14A, a stitching region 14B, a first peripheral region 16 and a plurality of alignment marks A11 and A12. The second mask pattern 20 includes a second component layout region 22, a stitching region 24A, a stitching region 24B, a second peripheral region 26, a plurality of alignment marks A21 and A22. The third mask pattern 30 includes a third component layout region 32, a stitching region 34A, a stitching region 34B, a third peripheral region 36, a plurality of alignment marks A31 and A32. The fourth mask pattern 40 includes a fourth component layout region 42, a stitching region 44A, a stitching region 44B, a fourth peripheral region 46, a plurality of alignment marks A41 and A42.

In the subsequent stitching step, the first mask pattern 10, the second mask pattern 20, the third mask pattern 30 and the fourth mask pattern 40 are respectively formed on the substrate 100, and the patterns are stitched with each other. More specifically, the stitching region 14A of the first mask pattern 10 will be stitched with the stitching region 24A of the second mask pattern 20, and the alignment marks A11 will overlap with the alignment marks A21. The stitching region 14B of the first mask pattern 10 will be stitched with the stitching region 34B of the third mask pattern 30, and the alignment marks A12 will overlap with the alignment marks A32. The stitching region 24B of the second mask pattern 20 will be stitched with the stitching region 44B of the fourth mask pattern 40, and the alignment marks A22 will overlap with the alignment marks A42. The stitching region 34A of the third mask pattern 30 will be stitched with the stitching region 44A of the fourth mask pattern 40, and the alignment marks A31 will overlap with the alignment marks A41.

Although this embodiment is applied to four mask pattern stitching steps, the concept of this embodiment is similar to that of the above-mentioned second embodiment, so some elements or regions, such as wires 104, electronic components C, first peripheral region 16, etc., have the same or similar characteristics as those corresponding to the above-mentioned second embodiment, although they are not described in detail. For simplicity of description, the features of these elements or regions can be described with reference to the above embodiments, and will not be repeated here.

In this embodiment, a part of alignment marks (for example, the alignment marks A11, the alignment marks A31, the alignment marks A32 and the alignment marks A42) are arranged in the component layout region by using a concept similar to that of the above-mentioned second embodiment, so that the area of the corresponding stitching region can be greatly reduced, thereby increasing the available area of the overall component layout region. Taking an actual example as an illustration, as shown in FIG. 5, the areas of the stitching region 14A, the stitching region 34A, the stitching region 34B and the stitching region 44B are all greatly reduced, and the corresponding alignment marks are moved to the component layout region next to the reduced stitching region. For example, the alignment marks A11 are arranged in the first component layout region 12 next to the stitching region 14A, the alignment marks A31 are arranged in the third component layout region 32 next to the stitching region 34A, the alignment marks A32 are arranged in the third component layout region 32 next to the stitching region 34B, and the alignment marks A42 are arranged in the fourth component layout region 42 next to the stitching region 44B. In each of the above-mentioned component layout regions with increased usable area, electronic components C are included and arranged beside the corresponding stitching regions. In other words, the extra area can be effectively used to arrange electronic components, so as to achieve the effect of increasing the density of components.

Based on the above description and drawings, the present invention provides a semiconductor stitching structure, which includes a substrate 100, a first mask pattern 10 defined on the substrate, a first component layout region 12 and a first stitching region 14′, a second mask pattern 20 defined on the substrate 100, a second component layout region 22 and a second stitching region 24′, and an overlapping stitching region 102′. The overlapping stitching region 102′ is the overlapping part of the first stitching region 14′ of the first mask pattern 10 and the second stitching region 24′ of the second mask pattern 20, a plurality of bridging wires W are located on the substrate 100 in the overlapping stitching region 102′, and a plurality of alignment marks (i.e., the first alignment mark A1 and the second alignment mark A2) are located in the first component layout region 12 on the substrate 100 (please refer to the embodiment shown in FIGS. 3-4).

In some embodiments of the present invention, the plurality of alignment marks include a plurality of first alignment marks A1 and a plurality of second alignment marks A2, and the plurality of first alignment marks A1 and the plurality of second alignment marks A2 are not located in the overlapping stitching region 102′.

In some embodiments of the present invention, each first alignment mark A1 and each second alignment mark A2 overlap each other.

In some embodiments of the present invention, each first alignment mark A1 and each second alignment mark A2 are arranged beside the overlapping stitching region 102′.

In some embodiments of the present invention, the first alignment marks A1 and the second alignment marks A2 are located only in the first component layout region 12, but not in the second component layout region 22.

In some embodiments of the present invention, an area of the first component layout region 12 is larger than an area of the second component layout region 22, and the ratio of the area of the first stitching region 14′ to the area of the second stitching region 24′ is less than 1/10. Referring to FIG. 4, for example, the width of the first stitching region 14′ is about 0.2 micron, while the width of the second stitching region 24′ is about 200 micron. Since the area of the first stitching region 14′ is greatly reduced, the usable area of the first component layout region 12 is also increased, so the area of the first component layout region 12 is larger than that of the second component layout region 22.

In some embodiments of the present invention, the first mask pattern 10 further includes a first peripheral region 16 located around the first component layout region 12, and further includes a plurality of third alignment marks A3 located in the first peripheral region 16.

In some embodiments of the present invention, the second mask pattern 20 further includes a second peripheral region 26 located around the second component layout region 22, and further includes a plurality of fourth alignment marks A4 located in the second peripheral region 26.

The invention further provides a method for manufacturing a semiconductor stitching structure, which comprises providing a substrate 100, providing a first mask pattern 10 and a second mask pattern 20, and transferring the patterns of the first mask pattern 10 and the second mask pattern to the substrate 100 to form a first mask pattern 10 on the substrate 100, wherein the first mask pattern 10 comprises a first component layout region 12, a first stitching region 14′ and a plurality of first alignment marks A1. Transferring the pattern of the second mask pattern 20 to the substrate 100 to form a second mask pattern 20 on the substrate 100, wherein the second mask pattern 20 comprises a second component layout region 22, a second stitching region 24′ and a plurality of second alignment marks A2, wherein the overlapping part of the first stitching region 14′ and the second stitching region 24′ is defined as an overlapping stitching region 102′, and a plurality of first alignment marks A1.

In some embodiments of the present invention, a plurality of first alignment marks A1 and a plurality of second alignment marks A2 are located in the first component layout region 12 on the substrate 100, but not in the second component layout region 22.

In some embodiments of the present invention, the first alignment mark A1 and the second alignment mark A2 overlap each other in the first component layout region 12.

In some embodiments of the present invention, a mask layer 28 is included in the second stitching region 24′ on the second mask pattern 20.

In some embodiments of the present invention, at least one first wire (the wire 104 located in the first component layout region 12) is located in the first component layout region 12, at least one second wire (the wire 104 located in the second component layout region 22) is located in the second component layout region 22, and at least one bridging wire W is located in the overlapping stitching region 102′, wherein the first wire 104, the second wire 104 and the bridging wire W are electrically connected with each other.

In some embodiments of the present invention, during the process for forming the second mask pattern 20 on the substrate 100, the mask layer 28 and the first wires 104 in the first component layout region 12 are overlap with each other.

In some embodiments of the present invention, an area of the first component layout region 12 is larger than an area of the second component layout region 22, and the ratio of the area of the first stitching region 14′ to the area of the second stitching region 24′ is less than 1/10 (taking FIG. 4 as an example, the width of the first stitching region 14′ is about 0.2 microns, and the width of the second stitching region 24′ is about 200 microns, in the condition of the same length, the area of the first stitching region 14′ is much smaller than that of the second stitching region 24′)

In some embodiments of the present invention, each first alignment mark A1 and each second alignment mark A2 are arranged beside the overlapping stitching region 102′.

In some embodiments of the present invention, the first mask pattern 10 further includes a first peripheral region 16 around the first component layout region 12, and further includes a plurality of third alignment marks A3 located in the first peripheral region 16.

In some embodiments of the present invention, the second mask pattern 20 further includes a second peripheral region 26 located around the second component layout region 22, and further includes a plurality of fourth alignment marks A4 located in the second peripheral region 26.

In some embodiments of the present invention, the second stitching region 24′ overlap s a part of the first component layout region 12.

In some embodiments of the present invention, a width of the first stitching region 14′ ranges from 0.1 micron to 0.3 micron, and a width of the second stitching region 24′ ranges from 100 microns to 300 microns.

The invention is characterized by providing a semiconductor stitching structure and a manufacturing method thereof. The semiconductor stitching structure is formed on a substrate or a material layer by a first photomask and a second photomask through respective exposure processes. It is worth noting that since the first alignment mark on the first photomask is set in the first component layout region, the area of the first stitching region of the first photomask can be minimized. For example, the width of the second stitching region on the second photomask is about 200 microns, but the width of the first stitching region of the first photomask only needs to be 0.2 microns. In addition, the invention can also be applied to stitching patterns of more different masks. By using the structure and method provided by the invention, when two mask patterns are adjacent to each other and stitched, the stitching region of one mask can be reduced to almost negligible, so compared with the traditional technology, the area of the stitching region can be reduced by about half, thereby improving the space of the component layout region on the mask and improving the component density. The invention is suitable for manufacturing large-area chips, such as display chips, or applied to fields such as VR (virtual reality) and AR (augmented reality).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor stitching structure, comprising:
a substrate;
a first mask pattern defined on the substrate, and the first mask pattern comprises a first component layout region and a first stitching region;
a second mask pattern defined on the substrate, and the second mask pattern comprises a second component layout region and a second stitching region;
an overlapping stitching region, wherein the overlapping stitching region is an overlapping part of the first stitching region of the first mask pattern and the second stitching region of the second mask pattern;
a plurality of bridging wires located on the substrate and in the overlapping stitching region; and
a plurality of alignment marks located in the first component layout region on the substrate.

2. The semiconductor stitching structure according to claim 1, wherein the plurality of alignment marks comprise a plurality of first alignment marks and a plurality of second alignment marks, and the plurality of first alignment marks and the plurality of second alignment marks are not located in the overlapping stitching region.

3. The semiconductor stitching structure according to claim 2, wherein each of the first alignment marks and each of the second alignment marks overlap each other.

4. The semiconductor stitching structure according to claim 2, wherein each of the first alignment marks and each of the second alignment marks are arranged beside the overlapping stitching region.

5. The semiconductor stitching structure according to claim 2, wherein each of the first alignment marks and each of the second alignment marks are located only in the first component layout region, but not in the second component layout region.

6. The semiconductor stitching structure according to claim 1, wherein an area of the first component layout region is larger than an area of the second component layout region, and the ratio of the area of the first stitching region to the area of the second stitching region is less than 1/10.

7. The semiconductor stitching structure according to claim 1, wherein the first mask pattern further comprises a first peripheral region around the first component layout region, and further comprises a plurality of third alignment marks located in the first peripheral region.

8. The semiconductor stitching structure according to claim 1, wherein the second mask pattern further comprises a second peripheral region around the second component layout region, and further comprises a plurality of fourth alignment marks located in the second peripheral region.

9. A method for manufacturing a semiconductor stitching structure, comprising:
providing a substrate;
providing a first mask pattern and a second mask pattern;
forming the first mask pattern on the substrate, wherein the first mask pattern comprises a first component layout region, a first stitching region and a plurality of first alignment marks;
forming the second mask pattern on the substrate, wherein the second mask pattern comprises a second component layout region, a second stitching region and a plurality of second alignment marks, wherein the overlapping part of the first stitching region and the second stitching region is defined as an overlapping stitching region, and the plurality of first alignment marks and the plurality of second alignment marks are not located in the overlapping stitching region on the substrate.

10. The method for manufacturing a semiconductor stitching structure according to claim 9, wherein the plurality of first alignment marks and the plurality of second alignment marks are located in the first component layout region on the substrate, but not in the second component layout region.

11. The method for manufacturing a semiconductor stitching structure according to claim 9, wherein the first alignment mark and the second alignment mark overlap each other in the first component layout region.

12. The method for manufacturing a semiconductor stitching structure according to claim 9, wherein the second stitching region of the second mask pattern further comprises a mask layer.

13. The method for manufacturing a semiconductor stitching structure according to claim 12, further comprising at least one first wire located in the first component layout region, at least one second wire located in the second component layout region, and at least one bridging wire located in the overlapping stitching region, wherein the first wire, the second wire and the bridging wire are electrically connected with each other.

14. The manufacturing method of the semiconductor stitching structure according to claim 13, wherein the mask layer and the first wire in the first component layout region overlap each other in the process of forming the second mask pattern on the substrate.

15. The method for manufacturing a semiconductor stitching structure according to claim 9, wherein an area of the first component layout region is larger than an area of the second component layout region, and the ratio of the area of the first stitching region to the area of the second stitching region is less than 1/10.

16. The method for manufacturing a semiconductor stitching structure according to claim 9, wherein each of the first alignment marks and each of the second alignment marks are arranged beside the overlapping stitching region.

17. The method for manufacturing a semiconductor stitching structure according to claim 9, wherein the first mask pattern further comprises a first peripheral region around the first component layout region, and further comprises a plurality of third alignment marks located in the first peripheral region.

18. The method for manufacturing a semiconductor stitching structure according to claim 9, wherein the second mask pattern further comprises a second peripheral region around the second component layout region, and further comprises a plurality of fourth alignment marks located in the second peripheral region.

19. The method for manufacturing a semiconductor stitching structure according to claim 9, wherein the second stitching region overlaps a part of the first component layout region.

20. The method for manufacturing a semiconductor stitching structure according to claim 9, wherein a width of the first stitching region is between 0.1 micron and 0.3 micron, and a width of the second stitching region is between 100 micron and 300 micron.
